(19) United States
(12) Patent Application Publication
(10) Pub. No.: US 2025/0274053 A1
(43) Pub. Date: Aug. 28, 2025

(54) METHOD FOR PRODUCING AN INVERTER AND INVERTER

(71) Applicant: MAGNA Powertrain GmbH & Co KG, Lannach (AT)

(72) Inventors: Birgit Lipp, Markt Hartmannsdorf (AT); Thomas Schnabel, Asten (AT); Markus Reiterer, Eichkoegl (AT); Alexander Dietrich, Ehrenhausen (AT)

(21) Appl. No.: 18/858,796

(22) PCT Filed: Apr. 3, 2023
(86) PCT No.: PCT/EP2023/058606

§ 371 Date: Oct. 22, 2024

(30) Foreign Application Priority Data
Apr. 22, 2022 (DE) 10 2022 203 946.7

(51) Int. Cl. H02M 7/00

(52) U.S. Cl. CPC H02M 7/003

(57) ABSTRACT

A method for producing an inverter incldues installing at least one filter assembly and one assembly for intermediate circuit capacitorsin an inverter housing on busbars. The individual components of the filter assembly and the assembly of the intermediate circuit capacitors are arranged optimally with respect to one another. The filter assembly and the assembly for intermediate circuit capacitors are jointly fastened in the inverter housing or a partial housing within the inverter housing using a potting compound and are thermally connected.

### CROSS-REFERENCE TO RELATED APPLICATIONS

This application is a National Stage of International Application No. PCT/EP2023/058606, filed on Apr. 3, 2023, which claims priority to DE 10 2022 203 946.7, filed on Apr. 22, 2022. The entire disclosures of each of the above applications are incorporated herein by reference.

### TECHNICAL FIELD

The present disclosure relates to a method for producing an inverter, wherein at least one filter assembly and one assembly for intermediate circuit capacitors are installed in an inverter housing on busbars, and wherein the individual components of the filter assembly and the assembly of the intermediate circuit capacitors are arranged optimally with respect to one another.

The present disclosure further relates to an inverter which is produced by the method.

### BACKGROUND

In electric vehicles, power inverters for drive motors constitute a key component for functionality and security. The power inverter—also described as an inverter—supplies electric motors with three-phase AC, and ensures that the latter are set to the correct torque and the correct speed. During braking and “cruising”, the electric machine functions as a generator, wherein the resulting power can be re-injected into the battery by the inverter during regenerative braking.

Known inverters consist of large assemblies, which include power modules and intermediate circuit capacitors, together with a filter unit, etc. For the mounting of the inverter in an inverter housing, prefabricated assemblies are frequently employed.

In many cases, the layout of inverters is such that the intermediate circuit capacitor and the EMC (electromagnetic compatibility) filter unit are considered as two separate assemblies and, as such, on the assembly line, are connected to one another in the inverter housing and to surrounding components.

The intermediate circuit capacitor unit includes capacitors which are embedded in a plastic housing and are contact-connected to busbars. In each case, both ends of the busbars are led out of the casting and bonded by welding to busbars in the direction of the power module assembly and in the direction of the filter unit assembly.

Although the filter unit assembly is not embedded, subcomponents such as, e.g. the ferrite core, are adhesively bonded in a plastic carrier shell for the purposes of positioning.

The assembly of intermediate circuit capacitors is a vendor part, such that the design of busbars cannot be influenced, and must be accepted as designed by the vendor.

Accordingly, connection of the assembly of intermediate circuit capacitors to other assemblies is not straightforward.

The embodiment of complex structures at the transition to the filter unit is therefore necessary, as the busbars only project from the cast housing at positions which are defined by the supplier.

A prefabricated intermediate circuit capacitor assembly is contacted with the inverter housing via an intermediate layer. This means that, for the intermediate circuit capacitor assembly, i.e. both for the capacitors and for the busbars, said assembly is thermally connected to the inverter housing via a plurality of polymer layers, and thus cannot be cooled in an ideal manner.

Likewise, optimum cooling of the filter unit assembly is not provided. Busbars in the region of the filter unit assembly are not thermally connected to the inverter housing, and must therefore be configured with a large cross-section, in order to prevent the localized generation of excessively high temperatures.

DE 10 2021 110 983 A1 discloses an EMC filter device for the power electronics of an electric machine, having an electrical conductor structure, at least one capacitance which is coupled to the conductor structure, and at least one inductance which cooperates with the conductor structure, wherein the conductor structure comprises at least two individual and mutually isolated conductive layers. The filter assembly is fitted to the housing by means of an elastic and thermally conductive adhesive layer or potting compound layer. In the filter assembly, inductances are installed on cores.

DE 11 2021 001 363 T5 discloses a power converter device which achieves both a reduction in size and an improvement of cooling efficiency, and which thus assumes an improved reliability. The power converter device contains a power conversion circuit unit, which converts DC power into AC power, a flow path receptacle body, which permits the flow of a coolant for cooling the power conversion circuit, a filter circuit unit, which suppresses electrical noise on a wire for the transmission of DC power, and a filter housing section which accommodates the filter circuit unit, wherein the filter housing section is integrally formed with the flow path receptacle body, and a gap between the filter housing section and the filter circuit unit is filled with a first resin.

SUMMARY

The object of the present disclosure is to provide a method for an improved layout of assemblies, in the interests of better cooling.

This object is fulfilled by a method for producing an inverter, wherein at least one filter assembly and one assembly for intermediate circuit capacitors are installed in an inverter housing on busbars, wherein the individual components of the filter assembly and the assembly of the intermediate circuit capacitors are arranged optimally with respect to one another, and wherein the filter assembly and the assembly for intermediate circuit capacitors are jointly fastened in the inverter housing, or in a partial housing within the inverter housing, by way of a potting compound, and are thermally connected.

In particular, consideration of the intermediate circuit capacitor unit and the filter unit in combination permits the busbars to be configured with a more flexible and material-saving design. Unnecessary directional changes dictated by an existing supply-side cast housing can be omitted. Separate intermediate circuit capacitors, on the grounds of their variable number and positioning, can be selected as common parts for further products.

The fullness level of potting compound is selected such that, in the internal cross-section of the ferrite core, an air gap is left above the fullness level, in order to prevent any functional impairment.

During the casting of the potting compound, the inverter housing is filled in a region in which two levels of the housing base are present. These two levels permit the fullness level to be adapted to the dictates of the intermediate circuit capacitors and the ferrite core.

If intermediate circuit capacitors with a dedicated housing are employed, these are connected above the busbars, and are only embedded up to the fullness level in the region of connections to the busbars.

If intermediate circuit capacitors with no dedicated housing are employed, these are connected below the busbars, and are fully embedded in combination therewith up to the fullness level.

Intermediate circuit capacitors are supplied pre-embedded in a housing, or supplied with no housing, and are contact-connected to the busbars wherein, in this case, the surrounding plastic at the connection points, in addition to a thermal function, specifically and additionally executes a mechanical fixing function.

Potting compounds are advantageous for electrically powered vehicles in multiple respects. In the event of the occurrence of thermal spikes, they improve the discharge of heat, and thus enhance the thermal resistance of the assembly. They also deliver protection against chemicals, and provide additional mechanical stability.

By the encapsulation of components in a common DC assembly, all electrical and electronic components are cooled more effectively. This means that, particularly in the region of the filter unit, busbars can be configured with a smaller cross-section.

In turn, the ferrite core can be adapted and reduced in size accordingly. By the direct encapsulation of the DC module in the inverter housing, a number of previously required components can be omitted, e.g. a cast housing and spacers in the case of the intermediate circuit capacitor, and a plastic carrier shell with adhesive in the case of the filter unit. By the direct thermal contact of components with the inverter housing via the potting compound material, the thermal path is shortened, in a manner which particularly affects the capacitors and busbars in the region of capacitors.

The object is further fulfilled by an inverter which is produced according to the method.

### BRIEF DESCRIPTION OF THE DRAWINGS

The present disclosure is described below by way of example with reference to the drawings.

FIG. 1 shows a partial top view of an inverter,

FIG. 2 shows a sectional image of a first embodiment, and

FIG. 3 shows a second embodiment.

### DETAILED DESCRIPTION

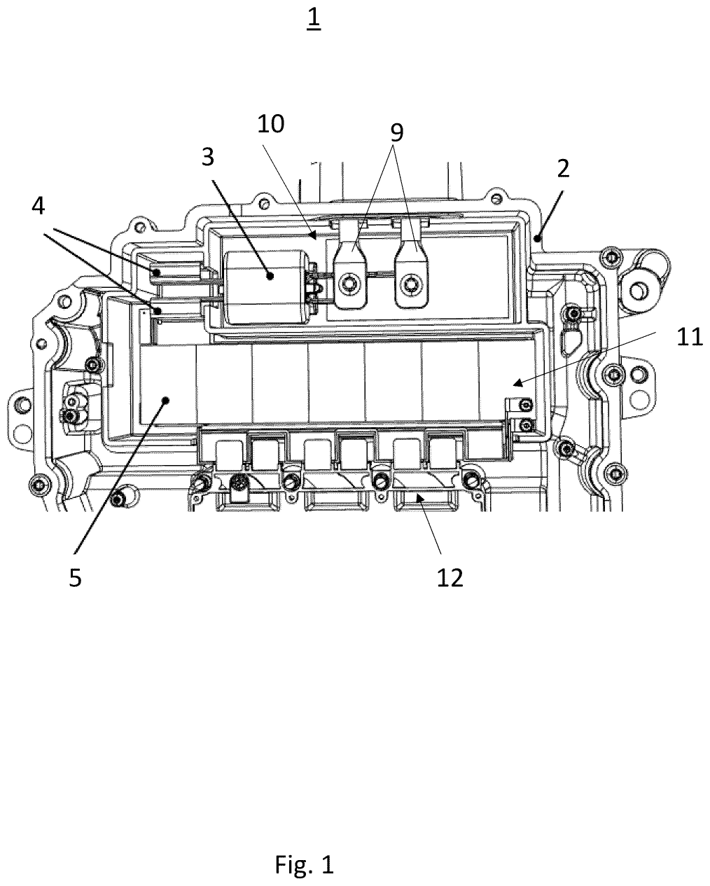

FIG. 1 shows a top view of assemblies of an inverter 1 in an inverter housing 2. Via a DC connection 9, the inverter 1 is connected to a DC current source, which may be a battery.

The DC connection 9 is connected to busbars 4, which are enclosed by a ferrite core 3 at the input side. The DC connection 9, busbars 4, and ferrite core 3 form main components of a filter assembly 10.

Further down-circuit, the busbars 4 are connected to the assembly of intermediate circuit capacitors 11, which may also be referred to as an intermediate circuit capacitor assembly. The power electronics assembly 12 is illustrated by way of a further assembly.

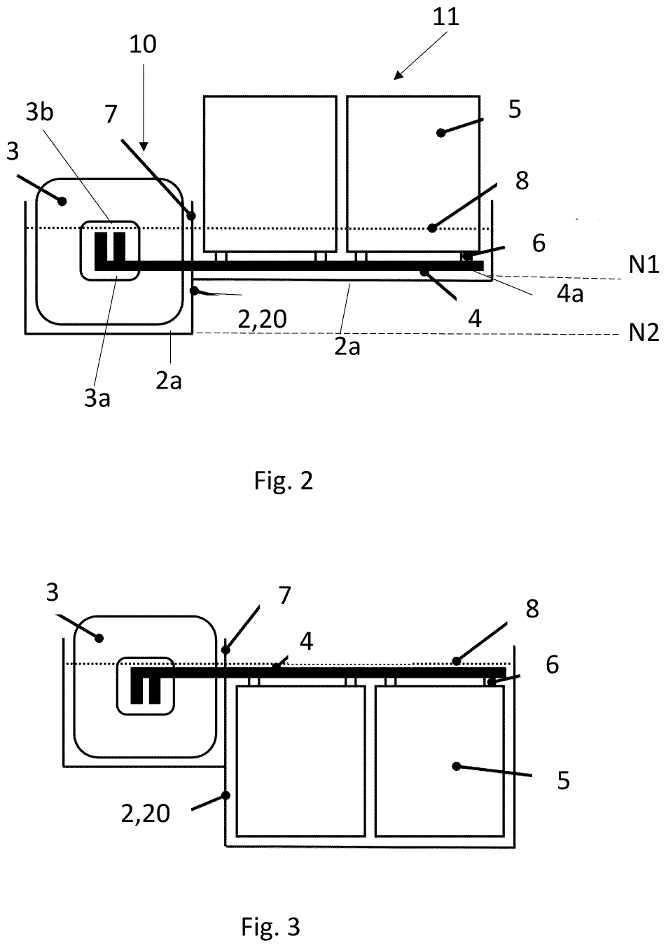

FIGS. 2 and 3 show the two assemblies, namely, the filter assembly 10 and the intermediate circuit capacitor assembly 11, in a perpendicular section to the top view represented in FIG. 1.

The filter assembly 10 is mounted in a common inverter housing 2, wherein the ferrite core 3 is enclosed by an EMC protective wall 7. The busbars 4 are routed in the ferrite core 3 perpendicularly to the image plane, and emerge below the intermediate circuit capacitors 5. The intermediate circuit capacitors are electrically connected to the busbars by means of contact points 6.

FIGS. 2 and 3 are distinguished in that, in FIG. 2, the intermediate circuit capacitors 5 are arranged above the busbars 4 whereas, in the embodiment according to FIG. 3, they are installed below the busbars 4.

Electronic components of the intermediate circuit capacitor assembly 11 and the filter assembly 10 are mounted in the inverter housing 2 as individual components. The intermediate circuit capacitor assembly 11 includes separate capacitors 5, each of which, subject to availability, are pre-embedded in a housing, or can also be employed without a housing. The individual capacitors 5 are connected to the busbars 4, which are routed in parallel and are configured with a thin intermediate insulating layer 4a.

Once all the assembly components of the filter assembly 10 and the intermediate circuit capacitor assembly 11 have been fastened in the housing and electrically connected, components are directly embedded in the inverter housing 2 by way of a thermally conductive plastic compound, also known as a potting compound, and are thermally and mechanically connected to the inverter housing 2. The casting process of the compound is completed, for example, by way of a casting process which is executed under low pressure and at a low temperature.

Components employed must be appropriate to the respective casting process. Further advantageous adaptations are executed with respect to the dimensioning of components. The cross-section of the busbars is thus reduced by half and, correspondingly, the ferrite core can also be configured with a smaller design.

At the position of the ferrite core 3, a maximum fullness level 8 of the potting compound is observed. Accordingly, the clear internal cross-section 3a of the ferrite core is not entirely filled, and a gap 3b is maintained.

Thus, depending upon the availability of capacitors 5 with or without a housing, it is necessary for the housing base 2a of the inverter housing 2, considered from the process perspective, to have different levels N1, N2. For the embedding of capacitors 5 with a dedicated housing, as represented in FIG. 2, only the region of the contact points 6 with the busbars 4 is embedded, and level N1 of the capacitors 5 is therefore higher, in comparison with level N2 of the ferrite core 3.

For the embedding of capacitors 5 with no housing, as represented in FIG. 3, the capacitors 5 are arranged entirely below the fullness level 8 of the potting compound, with the fullness level 8 being dictated by the internal cross-section 3a of the ferrite core 3.

Electrical/electronic components of the filter unit 10 and the intermediate circuit capacitor assembly 11 are assembled in the form of a DC module and directly embedded in the inverter housing 2 up to the specified fullness level 8, and are thermally and mechanically contacted accordingly, as a result of which the components are smaller, and the combination thereof permits greater flexibility with respect to the arrangement and routing of busbars.

In an alternative embodiment, the region of the inverter housing 2 in which the filter assembly 10 and the intermediate circuit capacitor assembly 11 are arranged is configured in the form of a separate partial housing 20.

The assembly is not embedded directly in the inverter housing 2, but in a separate partial housing 20, which is then contacted with the inverter housing 2. The separate partial housing 20 includes an electrically conductive material, wherein the separate partial housing 20 is embodied, for example, in the form of a two-component plastic housing. The partial housing 20 is made of an electrically non-conductive material, although the region of the filter unit is comprised of an EMC-shielding plastic.

### LIST OF REFERENCE SIGNS

1 Inverter
2 Inverter housing
2a Housing base
3 Ferrite core
3a Internal cross-section of ferrite core
3b Gap
4 Busbars
5 Intermediate circuit capacitor
6 Contact point
7 EMC protective wall
8 Fullness level
9 DC connection
10 Filter unit assembly
11 Assembly of intermediate circuit capacitors
12 Power electronics assembly
N1, N2 Level of the housing base 2a
20 Partial housing

What is claimed is:

1. A method for producing an inverter, the method comprising:
installing at least one filter assembly and at least one intermediate circuit capacitor assembly in an inverter housing on busbars,
wherein the the filter assembly includes a DC connection, the busbars and a ferrite core,
wherein the filter assembly and the intermediate circuit capacitor assembly are arranged with respect to one another such that the busbars (4) are configured with a flexible and material-saving design,
jointly fastening the filter assembly and the intermediate circuit capacitor assembly in the inverter a potting compound, and
thermally connecting the filter assembly and the intermediate circuit capacitor assembly,
setting a fullness level of the potting compound such that, in an internal cross-section of the ferrite core an air gap is left above the fullness level in the filter assembly.

2. The method as claimed in claim 1, wherein, during a casting of the potting compound, the inverter housing is filled in a region of the invertor housing in which two different levels of a housing base are present.

3. The method as claimed in claim 1, wherein the intermediate circuit capacitor assembly includes capacitors having a dedicated housing, wherein the capacitors are connected to the busbars above the busbars, and the capacitors are only embedded up to the fullness level in the region of connections to the busbars.

4. The method as claimed in claim 1, wherein the intermediate circuit capacitor assembly has capacitors with no dedicated housing, such that the capacitors are connected below the busbars, and the capacitors are fully embedded in combination with the busbars below the fullness level.

5. An inverter produced by the method as claimed in claim 1.

6. The method as claimed in claim 1, wherein the inverter housing includes a separate partial housing.

7. The method as claimed in claim 6, wherein the separate partial housing includes an electrically conductive material.

8. The method as claimed in claim 6, wherein the separate partial housing is in the form of a two-component plastic housing.

9. The method as claimed in claim 8, wherein the separate partial housing is made of an electrically non-conductive material, wherein a region of the filter unit is comprised of an EMC-shielding plastic.

10. The method as claimed in claim 1, wherein an EMC protective wall is disposed between the filter unit and the intermediate circuit capacitor assembly.

11. The method as claimed in claim 1, wherein components of the filter unit and the intermediate circuit capacitor assembly are electrically connected prior to a casting process of the potting compound disposed within the invertor housing.

12. The method as claimed in claim 1, wherein the fullness level is based on the position of the ferrite core and electrical contacts between the busbars and the capacitors, such that the air gap is disposed within the ferrite core above the fullness level and the contacts are embedded below the fullness level.

13. The method as claimed in claim 4, wherein the inverter housing is filled in a region of the invertor housing in which two different levels of a housing base are present, wherein the housing base in a region of the filter assembly is higher than the housing base in a region of the intermediate circuit capacitor assembly.

14. The method as claimed in claim 3, wherein the inverter housing is filled in a region of the invertor housing in which two different levels of a housing base are present, wherein the housing base in a region of the filter assembly is below the housing base in a region of the intermediate circuit capacitor assembly.

15. The method as claimed in claim 3, wherein the capacitors project above the fullness level and the capacitors are connected to the busbar via contact points disposed below the fullness level.
